(19) United States
(12) Patent Application Publication
(10) Pub. No.: US 2018/0269043 A1
(43) Pub. Date: Sep. 20, 2018

(54) MAGNETRON SPUTTERING APPARATUS AND FILM FORMATION METHOD USING MAGNETRON SPUTTERING APPARATUS

(71) Applicant: TOSHIBA MEMORY CORPORATION, Tokyo (JP)

(72) Inventors: Koji UEDA, Yokkaichi Mie (JP); Koji YAMAKAWA, Yokkaichi Mie (JP); Toshihiko NAGASE, Seoul (KR); Youngmin EEH, Seongnam-si Gyeonggi-do (KR); Kazuya SAWADA, Seoul (KR)

(73) Assignee: TOSHIBA MEMORY CORPORATION, Tokyo (JP)

(21) Appl. No.: 15/704,820

(22) Filed: Sep. 14, 2017

Related U.S. Application Data
(60) Provisional application No. 62/473,068, filed on Mar. 17, 2017.

(51) Int. Cl. H01J 37/34; C23C 14/35; H01L 21/02

(52) U.S. Cl. CPC H01J 37/3435; C23C 14/35; H01L 21/02266; H01J 37/3452; H01J 37/3405

(57) ABSTRACT

According to one embodiment, a film formation method using a magnetron sputtering apparatus including first and second magnets provided on first and second target holders, includes forming an insulating film on a wafer placed on a main surface of a wafer stage by sputtering first and second insulating targets set on the first and second target holders, wherein the wafer includes an effective area to be used for a product and an ineffective area outside the effective area, and when viewed from a direction perpendicular to the main surface of the wafer stage, at least a part of the first magnet overlaps the effective area of the wafer placed on the main surface of the wafer stage, and the entire second magnet does not overlap the effective area of the wafer placed on the main surface of the wafer stage.

### CROSS-REFERENCE TO RELATED APPLICATIONS

This application claims the benefit of U.S. Provisional Application No. 62/473,068, field Mar. 17, 2017, the entire contents of which are incorporated herein by reference.

### FIELD

Embodiments described herein relate generally to a magnetron sputtering apparatus and a film formation method using the magnetron sputtering apparatus.

### BACKGROUND

In the case of forming an insulating film using a magnetron sputtering apparatus, it is important to realize excellent film quality and excellent film thickness uniformity. However, it is not always easy to achieve excellent film quality and excellent film thickness uniformity.

### BRIEF DESCRIPTION OF THE DRAWINGS

FIG. 1 is a sectional view schematically showing the structure of a magnetron sputtering apparatus of an embodiment.

FIG. 2 is a plan view schematically showing the positional relationship among a wafer stage, first and second target holders, first and second insulating targets, and a wafer in the magnetron sputtering apparatus of the embodiment.

FIG. 3 is a plan view schematically showing the positional relationship among the wafer, the first and second insulating targets, and first and second magnets in the magnetron sputtering apparatus of the embodiment.

FIG. 4 is a graph showing a result of experiment for proving an effect of the magnetron sputtering apparatus of the embodiment.

FIG. 5 is a graph showing a result of experiment for proving an effect of the magnetron sputtering apparatus of the embodiment.

FIG. 6 is a graph showing a result of experiment for proving an effect of the magnetron sputtering apparatus of the embodiment.

FIG. 7 is a graph showing a result of experiment for proving an effect of the magnetron sputtering apparatus of the embodiment.

FIG. 8 is a sectional view schematically showing an example of the basic structure of a magnetoresistive element.

FIG. 9 is a sectional view schematically showing a state of forming a tunnel barrier layer of the magnetoresistive element using the magnetron sputtering apparatus of the embodiment.

### DETAILED DESCRIPTION

In general, according to one embodiment, a film formation method using a magnetron sputtering apparatus including a wafer stage, first and second target holders provided separately from each other above the wafer stage, and first and second magnets provided respectively on the first and second target holders, the method includes: forming an insulating film on a wafer placed on a main surface of the wafer stage by sputtering first and second insulating targets set respectively on the first and second target holders, wherein the wafer includes an effective area to be used for a product and an ineffective area outside the effective area, and when viewed from a direction perpendicular to the main surface of the wafer stage, at least a part of the first magnet overlaps the effective area of the wafer placed on the main surface of the wafer stage, and the entire second magnet does not overlap the effective area of the wafer placed on the main surface of the wafer stage.

Embodiments will be described hereinafter with reference to the accompanying drawings.

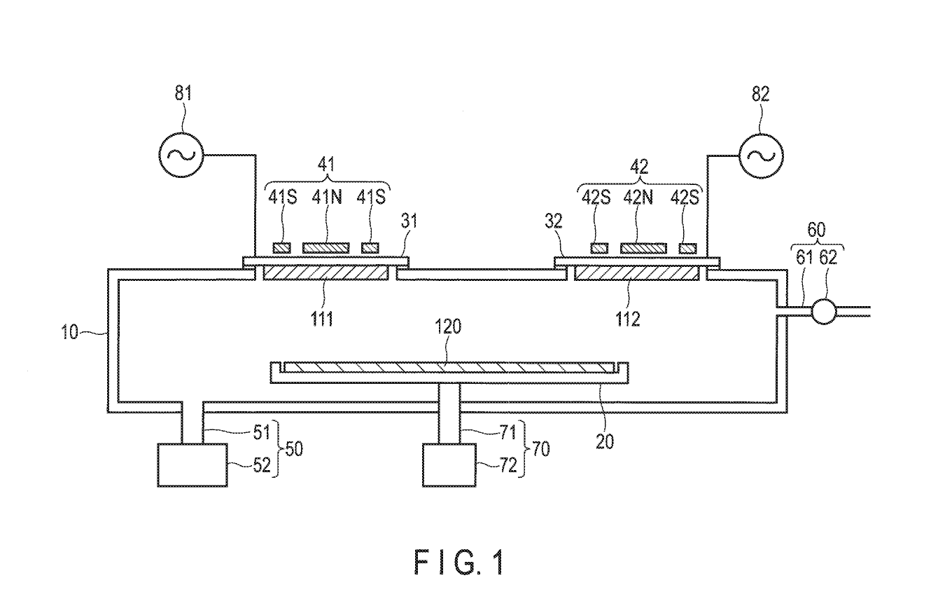

FIG. 1 is a sectional view schematically showing the structure of the magnetron sputtering apparatus of the embodiment.

As shown in FIG. 1, a wafer stage 20 is provided in a chamber 10, and a first target holder 31 and a second target holder 32 are provided separately from each other above the wafer stage 20. The first and second target holders 31 and 32 correspond to cathodes. A first magnet 41 is provided on the first target holder 31, and a second magnet 42 is provided on the second target holder 32. The first magnet 41 includes a north pole portion 41N in the central portion and a ring-shaped south pole portion 41S outside the north pole portion 41N. Similarly, the second magnet 42 includes a north pole portion 42N in the central portion and a ring-shaped south pole portion 42S outside the north pole portion 42N.

An exhaust system 50 which includes an exhaust pipe 51 and an exhaust pump 52 is connected to the chamber 10, and gas in the chamber 10 is discharged by the exhaust system 50. Further, a gas introduction system 60 which includes a gas introduction pipe 61 and a mass flow controller 62 is connected to the chamber 10, and predetermined gas is introduced into the chamber 10 by the gas introduction system 60.

A rotation system 70 which includes a rotating shaft 71 and a driver 72 is connected to the wafer stage 20, and the wafer stage 20 is rotated by the rotation system 70. Further, a high-frequency power source (RF power source) 81 is connected to the first target holder 31 and a high-frequency power source (RF power source) 82 is connected to the second target holder 32, and the power supplied from the high-frequency power sources 81 and 82 is used for performing sputtering.

In the sputtering, as a first insulating target 111 set on the first target holder 31 and a second insulating target 112 set on the second target holder 32 are sputtered, an insulating film is formed on a wafer (semiconductor wafer) 120 placed on the main surface of the wafer stage 20. The sputtering is performed while the wafer stage 20 is rotated by the rotation system 70.

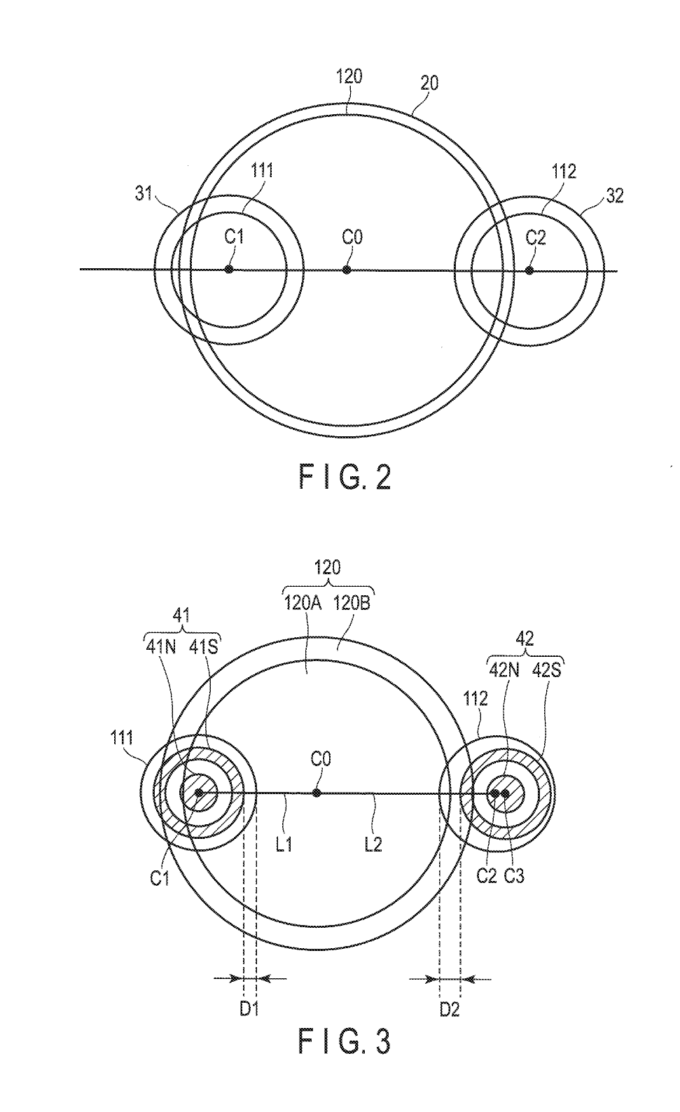

FIG. 2 is a plan view schematically showing the positional relationship among the wafer stage 20, the first and second target holders 31 and 32, the first and second insulating targets 111 and 112, and the wafer 120 in the magnetron sputtering apparatus shown in FIG. 1. More specifically, this is a plan view from a direction perpendicular to the main surface of the wafer stage 20. From another perspective, this is a plan view schematically showing the positional relationship among these elements based on the assumption that these elements are projected on a plane parallel to the main surface of the wafer stage 20.

Both of the first and second insulating targets 111 and 112 are used for forming an insulating film on the main surface of the wafer 120. Therefore, both of the first and second insulating targets 111 and 112 overlap the wafer 120. However, as will be described later, the overlapping amount of the second insulating target 112 is less than the overlapping amount of the first insulating target 111.

As shown in FIG. 2, a center C0 of the wafer stage 20 coincides with a center C0 of the wafer (semiconductor wafer) 120 placed on the main surface of the wafer stage 20. Further, a center C1 of the first target holder 31 coincides with a center C1 of the first insulating target 111 set on the first target holder 31, and a center C2 of the second target holder 32 coincides with a center C2 of the second insulating target 112 set on the second target holder 32.

Still further, with respect to the center C0 of the wafer stage 20, the first target holder 31 and the second target holder 32 are arranged on the opposite sides to each other. Therefore, with respect to the center C0 of the wafer 120, the first insulating target 111 and the second insulating target 112 are arranged on the opposite sides to each other. That is, the center C0 of the wafer 120 is located on the straight line which connects the center C1 of the first insulating target 111 and the center C2 of the second insulating target 112.

Further, the first target holder 31 and the second target holder 32 are asymmetrical with respect to the center C0 of the wafer stage 20. Therefore, the first insulating target 111 and the second insulating target 112 are asymmetrical with respect to the center C0 of the wafer 120. More specifically, the distance between the center C0 of the wafer 120 and the center C2 of the second insulating target 112 is greater than the distance between the center C0 of the wafer 120 and the center C1 of the first insulating target 111. Therefore, the overlapping amount of the second insulating target 112 is less than the overlapping amount of the first insulating target 111.

The first insulating target 111 is used for forming an insulating film entirely across the main surface of the wafer 120 at a high film formation rate. However, if only the first insulating target 111 is used for film formation, usually, the film formation rate of the peripheral portion of the wafer 120 will be lower than the film formation rate of the central portion of the wafer 120. As the second insulating target 112 is provided, the film formation rate of the peripheral portion can be increased, and consequently the uniformity of the film formation rate can be improved across the entire main surface of the wafer 120.

FIG. 3 is a plan view schematically showing the positional relationship among the wafer 120 placed on the main surface of the wafer stage 20, the first and second insulating targets 111 and 112 set respectively on the first and second target holders 31 and 32, and the first and second magnets 41 and 42 in the magnetron sputtering apparatus shown in FIG. 1. More specifically, this is a plan view from a direction perpendicular to the main surface of the wafer stage 20. From another perspective, this is a plan view schematically showing the positional relationship among these elements based on the assumption that these elements are projected on a plane parallel to the main surface of the wafer stage 20.

The wafer 120 includes an effective area 120A to be used for a product and an ineffective area 120B outside the effective area 120A. More specifically, the effective area 120A is an area which is used for a product such as an IC chip, and the ineffective area 120B is an area near the outer periphery of the wafer 120 which is not used for a product (IC chip). The ineffective area 120B may also include a circuit pattern which is not used for a product.

As shown in FIG. 3, at least a part of the first magnet 41 overlaps the effective area 120A of the wafer 120 placed on the main surface of the wafer stage 20, and the entire second magnet 42 does not overlap the effective area 120A of the wafer 120 placed on the main surface of the wafer stage 20. Further, at least a part of the second magnet 42 overlaps the ineffective area 120B of the wafer 120 placed on the main surface of the wafer stage 20.

Note that, as already stated, the first magnet 41 includes the north pole portion 41N in the central portion and the ring-shaped south pole portion 41S outside the north pole portion 41N. Similarly, the second magnet 42 includes the north pole portion 42N in the central portion and the ring-shaped south pole portion 42S outside the north pole portion 42N. Note that, the first magnet 41 here includes not only the north pole portion 41N and the south pole portion 41S but also a ring-shaped portion between the north pole portion 41N and the south pole portion 41S. Similarly, the second magnet 42 here includes not only the north pole portion 42N and the south pole portion 42S but also a ring-shaped portion between the north pole portion 42N and the south pole portion 42S.

To establish the above-described positional relationship, a center C3 of the second magnet 42 is deviated from the center C2 of the second insulating target 112. On the other hand, a center C1 of the first magnet 41 coincides with the center C1 of the first insulating target 111. Therefore, on the projection plane, assuming that a straight line connecting the center C0 of the wafer 120 and the center C1 of the first insulating target is a first straight line L1 and a straight line connecting the center C0 of the wafer 120 and the center C2 of the second insulating target 112 is a second straight line L2, a distance D2 between the edge of the second insulating target 112 and the edge of the second magnet 42 on the second straight line L2 is greater than a distance D1 between the edge of the first insulating target 111 and the edge of the first magnet 41 on the first straight line L1.

As described above, when viewed from the direction perpendicular to the main surface of the wafer stage 20, the entire second magnet 42 does not overlap the effective area 120A of the wafer 120 placed on the main surface of the wafer stage 20. As the second magnet 42 is arranged in such a position, an insulating film having excellent film quality and excellent film thickness uniformity can be formed on the main surface of the wafer 120. Explanations will be provided below.

In the case of forming an insulating film on the wafer using the magnetron sputtering apparatus, it is possible to improve energy efficiency for insulating film formation by reducing the distance between the insulating target and the wafer. In this case, to satisfy excellent film quality as well as excellent film thickness uniformity, it is essential to accurately determine the positional relationship between the second magnet 42 and the wafer 120.

As already stated, if only the first insulating target 111 is used for film formation, usually, the film formation rate of the peripheral portion of the wafer 120 will be lower than the film formation rate of the central portion of the wafer 120. As the second insulating target 112 is provided, the film formation rate of the peripheral portion can be increased, and consequently the uniformity of the film formation rate (film thickness uniformity) can be improved across the entire main surface of the wafer 120. In the case of improving the film thickness uniformity by increasing the film formation rate of the peripheral portion, it is preferable to increase the overlapping area of the second insulating target 112 and the wafer 120 to some extend. However, when the second magnet 42 and the wafer 120 overlap each other, there is a possibility that excess energy will be applied to the surface of the wafer 120 in the overlapping portion and will cause damage to the surface of the wafer 120.

In the present embodiment, since the entire second magnet 42 does not overlap the effective area 120A of the wafer 120, the above-described damage to the effective area 120A can be suppressed. That is, damage to an area of the wafer 120 which is used for a product can be suppressed. Further, at least a part of the second magnet 42 overlaps the ineffective area 120B of the wafer 120, and therefore the decrease in the film formation rate of the peripheral portion of the wafer 120 can also be suppressed. Consequently, according to the present embodiment, an insulating film having excellent film quality and excellent film thickness can be formed.

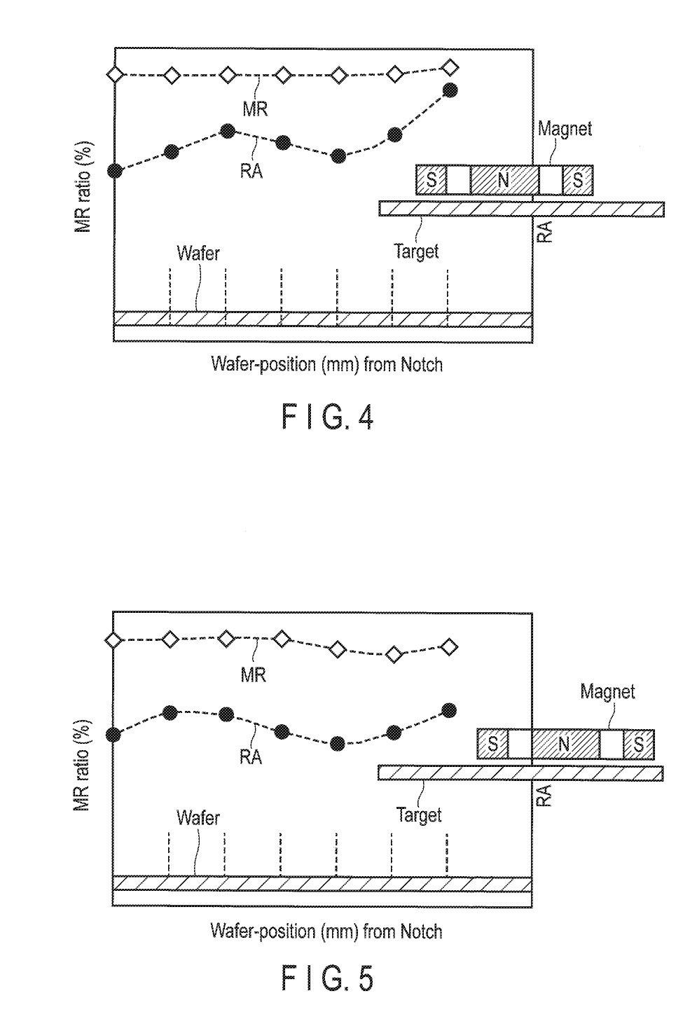

FIGS. 4 to 7 show results of experiment for proving the above-described effects. More specifically, these drawings show results of experiment in forming a tunnel barrier layer of a magnetoresistive element which will be described later by the magnetron sputtering apparatus. MgO is used as the material of the tunnel barrier layer.

FIGS. 4 and 5 show the distribution of the RA (sheet resistance) and the MR ratio of the magnetoresistive element within the wafer plane. FIG. 4 corresponds to the case of a comparative example, and FIG. 5 corresponds to the case of the present embodiment.

In FIGS. 4 and 5, the distribution of the MR ratio is substantially even. On the other hand, as to the distribution of the RA, the RA varies widely in the case shown in FIG. 4, while the RA varies slightly in the case shown in FIG. 5. Particularly, in the case shown in FIG. 4, the RA significantly increases in an area where the magnet and the wafer overlap each other. On the other hand, in the case shown in FIG. 5, since the magnet and the wafer do not overlap each other in the corresponding area, the RA does not increase much. Generally, the RA and the MR ratio are proportional, and therefore if the MR ratio remains unchanged and only the RA increases, the characteristics of the magnetoresistive element are degraded. It is considered that, in an area where the magnet and the wafer overlap each other, excess energy has caused damage to the surface of the wafer and degraded the characteristics of the element.

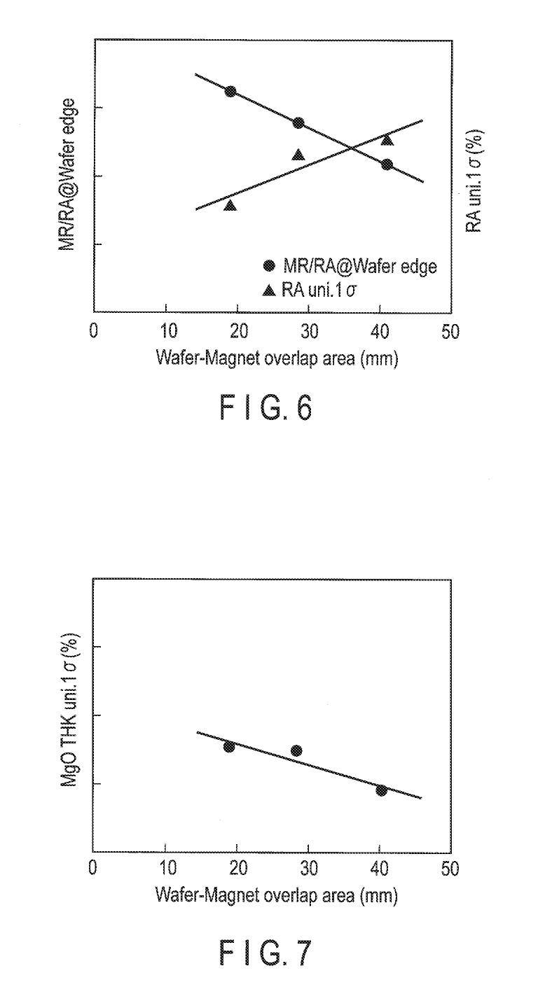

FIG. 6 shows the relationship between the width of the overlapping area of the magnet and the wafer, and the RA and the MR ratio (value standardized by the RA) of the magnetoresistive element. Since the RA value increases with increasing width of the overlapping area, the MR/RA value decreases with increasing width of the overlapping area. It has been confirmed that, as the width of the overlapping area increases, the element characteristics deteriorate.

FIG. 7 shows the relationship between the width of the overlapping area of the magnet and the wafer, and the thickness uniformity (uniformity within the wafer plane) of the MgO layer. As the width of the overlapping area increases, the thickness uniformity of the MgO layer improves. Therefore, in light of the thickness uniformity of the insulating film, it is preferable to increase the width of the overlapping area.

It is confirmed from the above experimental results (measurement results) that there is a preferable range of the width of the overlapping area of the magnet and the wafer. More specifically, the width of the overlapping area should preferably be in the range of 10 mm to 25 mm.

Next, a method of forming an insulating film using the magnetron sputtering apparatus of the present embodiment will be described. More specifically, a method of forming the tunnel barrier layer of the magnetoresistive element using the magnetron sputtering apparatus of the present embodiment will be described.

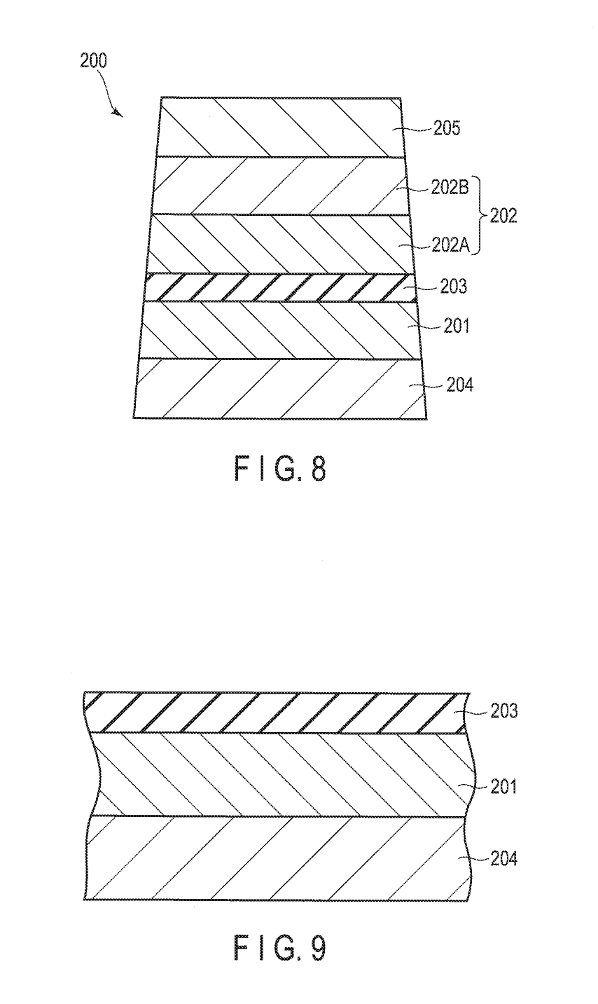

FIG. 8 is a sectional view schematically showing an example of the basic structure of the magnetoresistive element. Note that the magnetoresistive element is referred to also as a magnetic tunnel junction (MTJ) element.

A magnetoresistive element 200 shown in FIG. 8 includes a storage layer (first magnetic layer) 201 which has a variable magnetization direction perpendicular to the main surface thereof, a reference layer (second magnetic layer) 202 which has a fixed magnetization direction perpendicular to the main surface thereof, and a tunnel barrier layer (nonmagnetic layer) 203 which is provided between the storage layer 201 and the reference layer 202. The storage layer 201 is provided on the underlayer 204, and a cap layer 205 is provided on the reference layer 202. Note that a shift canceling layer which has a magnetization direction antiparallel to the magnetization direction of the reference layer 202 and cancels a magnetic field which is applied from the reference layer 202 to the storage layer 201 may be provided between the reference layer 202 and the cap layer 205.

The storage layer 201 contains at least iron (Fe) and boron (B) and may further contain cobalt (Co). For example, the storage layer 201 is formed of CoFeB.

The reference layer 202 includes a lower layer portion 202A and an upper layer portion 202B. The lower layer portion 202A contains at least iron (Fe) and boron (B) and may further contain cobalt (Co). For example, the lower layer portion 202A is formed of CoFeB. The upper layer portion 202B contains cobalt (Co) and at least one element selected from platinum (Pt), nickel (Ni), and palladium (Pd). For example, the upper layer portion 202B is formed of CoPt, CoNi, or CoPd.

The tunnel barrier layer 203 is an insulating layer and contains magnesium (Mg) and oxygen (O). For example, the tunnel barrier layer 203 is formed of MgO.

When the magnetization direction of the storage layer 201 and the magnetization direction of the reference layer 202 are parallel to each other, the magnetoresistive element 200 shows a low resistance state. When the magnetization direction of the storage layer 201 and the magnetization direction of the reference layer 202 are antiparallel to each other, the magnetoresistive element 200 shows a high resistance state. Therefore, the magnetoresistive element 200 can store binary data based on the resistance state. Further, according to the direction of current passing through the magnetoresistive element 200, the resistance state can be determined, that is, the binary data can be written.

As described above, when the magnetron sputtering apparatus of the present embodiment is used for forming the tunnel barrier layer 203 of the magnetoresistive element 200, the tunnel barrier layer 203 having excellent film quality and film thickness uniformity can be formed.

FIG. 9 is a sectional view schematically showing a state of forming the tunnel barrier layer 203 of the magnetoresistive element 200 using the magnetron sputtering apparatus of the present embodiment. Here, a magnesium oxide (MgO) layer is formed as the tunnel barrier layer 203.

Firstly, as shown in FIG. 1, the first and second insulating targets 111 and 112 are set respectively on the first and second target holders 31 and 32, and then the wafer 120 is placed on the wafer stage 20. As the first and second insulating targets 111 and 112, magnesium oxide (MgO) targets are used. The wafer 120 contains a semiconductor wafer, a transistor formed on the semiconductor wafer, and the like. Further, as shown in FIG. 9, the wafer 120 includes the underlayer 204 and the storage layer 201.

Then, air in the chamber 10 is discharged by the exhaust system 50, and predetermined gas is introduced into the chamber 10 by the gas introduction system 60. Subsequently, high-frequency power is supplied from the high-frequency power sources (RF power sources) 81 and 82 to the first and second target holders 31 and 32, and sputtering is started. In the sputtering, as the wafer stage 20 is rotated by the rotation system 70, the insulating film (MgO film) can be formed on the entire main surface of the wafer 120. In this way, the magnesium oxide layer (MgO layer) is formed on the storage layer 201 as the tunnel barrier layer 203.

Although illustrations of the subsequent processes are omitted, the reference layer 202 and the cap layer 205 are formed on the tunnel barrier layer 203. Further, as the stacked film formed through the above-described processes is patterned, the magnetoresistive element 200 shown in FIG. 8 will be obtained.

As described above, when the magnetron sputtering apparatus of the present embodiment is used for forming the tunnel barrier layer 203 of the magnetoresistive element 200, the tunnel barrier layer 203 having excellent quality can be formed, and consequently the magnetoresistive element 200 having excellent characteristics can be obtained.

Note that various insulating films having excellent quality can be formed by the magnetron sputtering apparatus of the present embodiment. For example, it is possible to form insulating films having excellent quality by using oxides such as a magnesium oxide, a calcium oxide, a barium oxide, a strontium oxide and a zirconium oxide, fluorides such as a magnesium fluoride, a calcium fluoride, a barium fluoride, a strontium fluoride and a zirconium fluoride, and the like, as the materials of the insulating films.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A film formation method using a magnetron sputtering apparatus comprising a wafer stage, first and second target holders provided separately from each other above the wafer stage, and first and second magnets provided respectively on the first and second target holders, the method comprising:
forming an insulating film on a wafer placed on a main surface of the wafer stage by sputtering first and second insulating targets set respectively on the first and second target holders, wherein
the wafer includes an effective area to be used for a product and an ineffective area outside the effective area, and when viewed from a direction perpendicular to the main surface of the wafer stage, at least a part of the first magnet overlaps the effective area of the wafer placed on the main surface of the wafer stage, and the entire second magnet does not overlap the effective area of the wafer placed on the main surface of the wafer stage.

2. The method of claim 1, wherein when viewed from the direction perpendicular to the main surface of the wafer stage, at least a part of the second magnet overlaps the ineffective area of the wafer placed on the main surface of the wafer stage.

3. The method of claim 1, wherein assuming that the wafer placed on the main surface of the wafer stage, and the first and second insulating targets set respectively on the first and second target holders are projected on a plane parallel to the main surface of the wafer stage, a distance between a center of the projected wafer and a center of the projected second insulating target is greater than a distance between the center of the projected wafer and a center of the projected first insulating target.

4. The method of claim 1, wherein assuming that the wafer placed on the main surface of the wafer stage, and the first and second insulating targets set respectively on the first and second target holders are projected on a plane parallel to the main surface of the wafer stage, a center of the projected wafer is located on a straight line connecting a center of the projected first insulating target and a center of the projected second insulating target.

5. The method of claim 1, wherein assuming that the wafer placed on the main surface of the wafer stage, the first and second insulating targets set respectively on the first and second target holders, and the first and second magnets are projected on a plane parallel to the main surface of the wafer stage, and that a straight line connecting a center of the projected wafer and a center of the projected first insulating target is a first straight line, and a straight line connecting a center of the projected wafer and a center of the projected second insulating target is a second straight line, a distance between an edge of the projected second insulating target and an edge of the projected second magnet on the second straight line is greater than a distance between an edge of the projected first insulating target and an edge of the projected first magnet on the first straight line.

6. The method of claim 1, wherein the insulating film is formed on the wafer while the wafer stage is rotated.

7. The method of claim 1, wherein the insulating film is formed of either an oxide or a fluoride.

8. The method of claim 1, wherein the insulating film is used in a magnetoresistive element including a first magnetic layer having a variable magnetization direction, a second magnetic layer having a fixed magnetization direction, and a nonmagnetic layer between the first magnetic layer and the second magnetic layer, as the nonmagnetic layer.

9. A film formation method using a magnetron sputtering apparatus comprising a wafer stage, first and second target holders provided separately from each other above the wafer stage, and first and second magnets provided respectively on the first and second target holders, the method comprising:
forming an insulating film on a wafer placed on a main surface of the wafer stage by sputtering first and second insulating targets set respectively on the first and second target holders, wherein
assuming that the wafer placed on the main surface of the wafer stage, the first and second insulating targets set respectively on the first and second target holders, and the first and second magnets are projected on a plane parallel to the main surface of the wafer stage, and that a straight line connecting a center of the projected wafer and a center of the projected first insulating target is a first straight line, and a straight line connecting the center of the projected wafer and a center of the projected second insulating target is a second straight line, a distance between an edge of the projected second insulating target and an edge of the projected second magnet on the second straight line is greater than a distance between an edge of the projected first insulating target and an edge of the projected first magnet on the first straight line.

10. The method of claim 9, wherein a distance between the center of the projected wafer and the center of the projected second insulating target is greater than a distance between the center of the projected wafer and the center of the projected first insulating target.

11. The method of claim 9, wherein the center of the projected wafer is located on a straight line connecting the center of the projected first insulating target and the center of the projected second insulating target.

12. The method of claim 9, wherein the insulating film is formed on the wafer while the wafer stage is rotated.

13. The method of claim 9, wherein the insulating film is formed of either an oxide or a fluoride.

14. The method of claim 9, wherein the insulating film is used in a magnetoresistive element including a first magnetic layer having a variable magnetization direction, a second magnetic layer having a fixed magnetization direction, and a nonmagnetic layer between the first magnetic layer and the second magnetic layer, as the nonmagnetic layer.

15. A magnetron sputtering apparatus comprising:
a wafer stage;
first and second target holders provided separately from each other above the wafer stage; and
first and second magnets provided respectively on the first and second target holders, wherein
assuming that a wafer placed on a main surface of the wafer stage, first and second insulating targets set respectively on the first and second target holders, and the first and second magnets are projected on a plane parallel to the main surface of the wafer stage, and that a straight line connecting a center of the projected wafer and a center of the projected first insulating target is a first straight line, and a straight line connecting the center of the projected wafer and a center of the projected second insulating target is a second straight line, a distance between an edge of the projected second insulating target and an edge of the projected second magnet on the second straight line is greater than a distance between an edge of the projected first insulating target and an edge of the projected first magnet on the first straight line.

16. The apparatus of claim 15, wherein a distance between the center of the projected wafer and the center of the projected second insulating target is greater than a distance between the center of the projected wafer and the center of the projected first insulating target.

17. The apparatus of claim 15, wherein the center of the projected wafer is located on a straight line connecting the center of the projected first insulating target and the center of the projected second insulating target.

18. The apparatus of claim 15, wherein the wafer includes an effective area to be used for a product and an ineffective area outside the effective area, and when viewed from a direction perpendicular to the main surface of the wafer stage, at least a part of the first magnet overlaps the effective area of the wafer placed on the main surface of the wafer stage, and the entire second magnet does not overlap the effective area of the wafer placed on the main surface of the wafer stage.

19. The apparatus of claim 18, wherein when viewed from the direction perpendicular to the main surface of the wafer stage, at least a part of the second magnet overlaps the ineffective area of the wafer placed on the main surface of the wafer stage.

20. The apparatus of claim 15, further comprising a rotation system for rotating the wafer stage.
